(19) United States
(12) Patent Application Publication
(10) Pub. No.: US 2009/0294933 A1
(43) Pub. Date: Dec. 3, 2009

(54) Lead Frame and Chip Package Structure and Method for Fabricating the Same

(75) Inventor: Chin-Ti Chen, Hsinchu (TW)

Correspondence Address: Eschweiler & Associates LLC;National City Bank Building, 629 Euclid Avenue, Suite 1000, Cleveland, OH, 44114, US

(73) Assignee: Powertech Technology Inc., Hsinchu (TW)

(21) Appl. No.: 12/240,362

(22) Filed: Sep. 29, 2008

(30) Foreign Application Priority Data
May 30, 2008 (TW) 097120265

(51) Int. Cl. H01L 23/495; H01L 21/00

(52) U.S. Cl. 257/666; 438/107; 257/E23.031

(57) ABSTRACT

The present invention discloses a lead frame and chip package structure, which comprises a plurality of leads including a plurality of inner leads and a plurality of outer leads; a plurality of chips arranged on a portion of the inner leads; a plurality of connecting wires electrically connecting the chips to the other inner leads; a support member arranged on the lower surface of the inner leads and having a fillister with an opening, wherein the backside of the opening faces the inner leads; and a resin encapsulant covering the leads, the chips, the connecting wires and the support member, and filling up the fillister with a portion of the outer leads and a portion of the surface of the support member being revealed. Further, the present invention also discloses a method for fabricating a lead frame and chip package structure, whereby the quality of a chip package is promoted.

### BACKGROUND OF THE INVENTION

1. Field of the Invention

The present invention relates to a lead frame and chip package structure, particularly to a lead frame and chip package structure and a 1 2 method for fabricating the same, which can promote the quality of a chip package structure.

2. Description of the Related Art

The objective of chip packaging is to provide the chip and the system with a mechanical strength to counteract external force in the working environment. However, resin injection is likely to generate a vertical pressure difference. The stress of pressure difference may distort the original structure, displace the chips, deviate the positions for wire bonding, cause short circuit, and expose the lead frame to outside the resin encapsulant, wherefore the chip package may be discarded.

Refer to FIG. 1a a diagram schematically showing a conventional semiconductor package structure. The conventional semiconductor package structure comprises a lead frame including leads 160, wherein the leads 160 have long leads 161 and short leads 165, and a gap is formed in between the long leads 161 and the short leads 165; a first chip 100 stuck to the long lead 161 and arranged in the gap; a second chip 101 stuck to the first chip 100; connecting wires 130 electrically connecting the first chip 100 and the second chip 101 to the long leads 161 and the short leads 165; and a resin encapsulant 150 covering the first chip 100, the second chip 101, the connecting wires 130, the long leads 161 and the short leads 165. Thereby, a package of a multi-chip stack is formed, and the electric performance thereof is promoted.

Refer to FIG. 1b a sectional view schematically showing the resin injection process of the conventional semiconductor package structure shown in FIG. 1a. In some traditional lead frames, the chip seat has four sides joined to the connection bars, and the chips are thus securely supported. The chip or chips of the conventional semiconductor package structure shown in FIG. 1a are carried by the long leads 161, but only the single sides of the long leads 161 are joined to the connection bars of the lead frame. During the resin injection process of the conventional semiconductor package structure shown in FIG. 1a, the vertical pressure difference of the resin flow will create a downward force, and the chips are likely to sink because of the weak support force of the leads, or even the long leads 161 may protrude out of the resin encapsulant 150. Further, the resin flow may also impact and tear the connecting wires 130 and thus cause the malfunction of the semiconductor package.

Refer to FIG. 2a a diagram schematically showing another conventional semiconductor package structure. The conventional semiconductor package structure comprises a lead frame having leads 260 and a chip seat 210 arranged in the central region defined by the inner ends of the leads 260. The chip seat 210 is joined to the lead frame by several support ribs 220. Refer to FIG. 2b. The lead frame features several downward protrusions 280 at four corners of the lower surface of the chip seat 210 or at the support ribs 220 joined to the four corners of the chip seat 210.

Refer to FIG. 2b a sectional view of a chip 200 and a lead frame 201 after packaging along the diagonal of the chip 200. The chip 200 is usually stuck to the chip seat 201 with an adhesive layer, and then resin is injected into the mold cavity to form a resin encapsulant. In the conventional lead frame, the protrusions 280 of the chip seat 210 are propped against the bottom of the mold, whereby the firmness of the chip seat 210 is increased, and whereby the chip seat 210 and the chip 200 are securely positioned during resin injection. However, the weight of the chip 200 and the vertical stress are sustained by only the protrusions 280 at four corners. According to the equation of pressure P=F/A, a smaller area has a greater pressure. Therefore, the protrusions 280 are burdened too much.

### SUMMARY OF THE INVENTION

One objective of the present invention is to provide a lead frame and chip package structure and a method for fabricating the same to solve the abovementioned problems. Particularly, the present invention is to provide a lead frame and chip package structure with a support member, wherein the support member is arranged on the lower surface of the inner leads to fix the leads and provide support force for the leads lest the leads be displaced during molding.

Another objective of the present invention is to provide a lead frame and chip package structure and a method for fabricating the same, wherein the mold directly props up the support member to prevent from the structural distortion caused by the vertical pressure difference of the resin flow during molding, whereby the chips inside the resin encapsulant will not be displaced, and the short circuit of the gold wires is prevented, and the quality of the chip package is promoted.

To achieve the abovementioned objectives, the present invention proposes a lead frame and chip package structure, which comprises a plurality of leads including a plurality of inner leads and a plurality of outer leads, wherein the outer leads jointly define a first plane, and the inner leads are connected to the outer leads and bent downward and then extended horizontally to jointly define a second plane; a plurality of chips arranged on a portion of the inner leads; a plurality of connecting wires electrically connecting the chips to the other inner leads; a support member arranged on the lower surface of the inner leads and having a fillister with an opening, wherein the backside of the opening faces the inner leads; and a resin encapsulant covering the leads, the chips, the connecting wires and the support member, and filling up the fillister, but revealing a portion of the outer leads and a portion of the surface of the support member.

To achieve the abovementioned objectives, the present invention also proposes a method for fabricating a lead frame and chip package structure, which comprises steps: providing a plurality of leads including a plurality of inner leads and a plurality of outer leads, wherein the outer leads jointly define a first plane, and the inner leads are connected to the outer leads and bent downward and then extended horizontally to jointly define a second plane; stacking a plurality of chips on the upper surface of a portion of the inner leads; using a plurality of connecting wires to electrically connect the chips to the other inner leads; arranging a support member on the lower surface of the inner leads, wherein the support member has a fillister with an opening, and the backside of the opening faces the inner leads; providing a mold having a mold cavity, propping up the support member, and revealing a portion of the outer leads; and injecting a resin encapsulant to cover the leads, the chips, the connecting wires and the support member and fill up the fillister with a portion of the outer leads and a portion of surface of the support member being revealed.

### BRIEF DESCRIPTION OF THE DRAWINGS

FIG. 1a and FIG. 1b are sectional views schematically showing a conventional semiconductor package structure;

FIG. 2a is a top view schematically showing another conventional semiconductor package structure;

FIG. 2b is a sectional view schematically showing the conventional semiconductor package structure shown in FIG. 2a;

FIG. 3 is a sectional view schematically showing a lead frame and chip package structure according to one embodiment of the present invention; and

FIGS. 4a-4e are sectional views schematically the steps of a method of fabricating a lead frame and chip package structure according to one embodiment of the present invention.

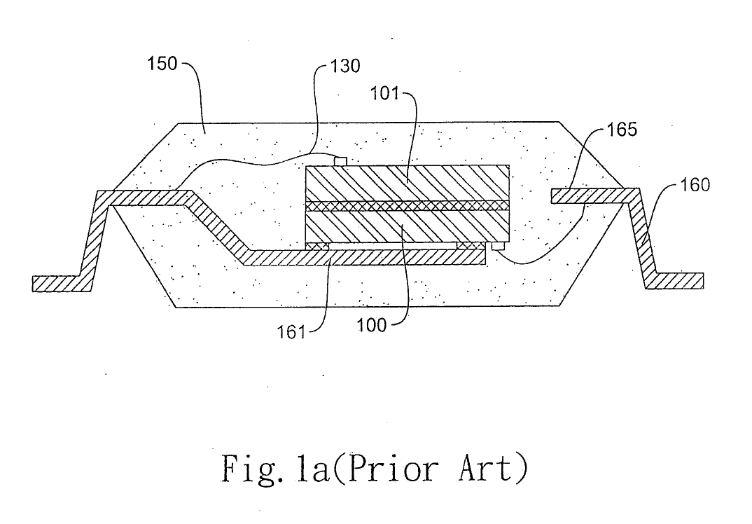

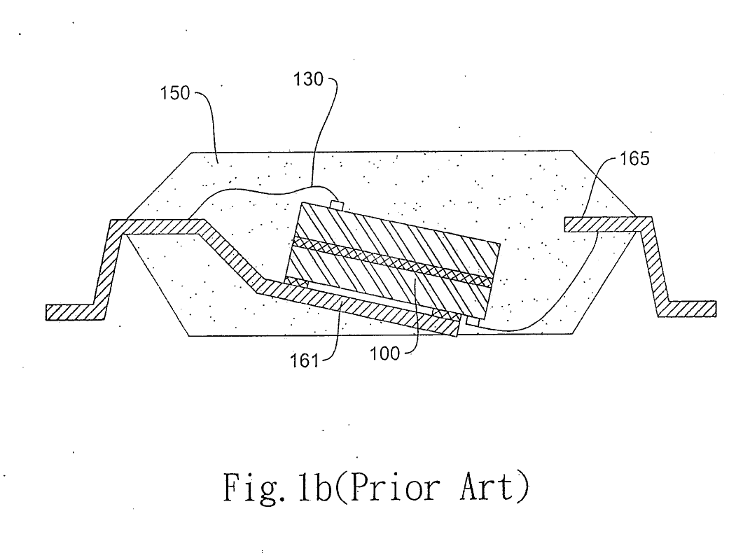

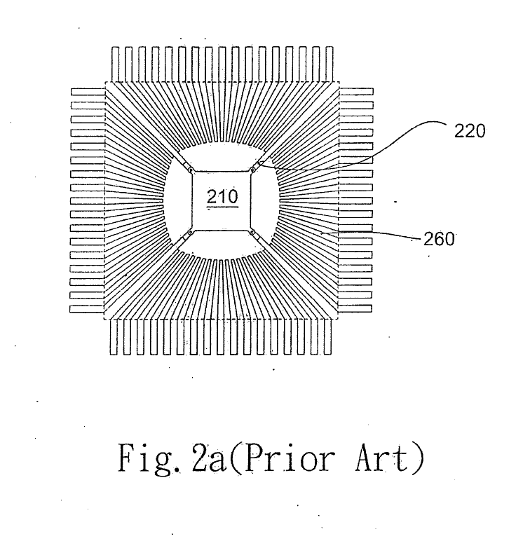

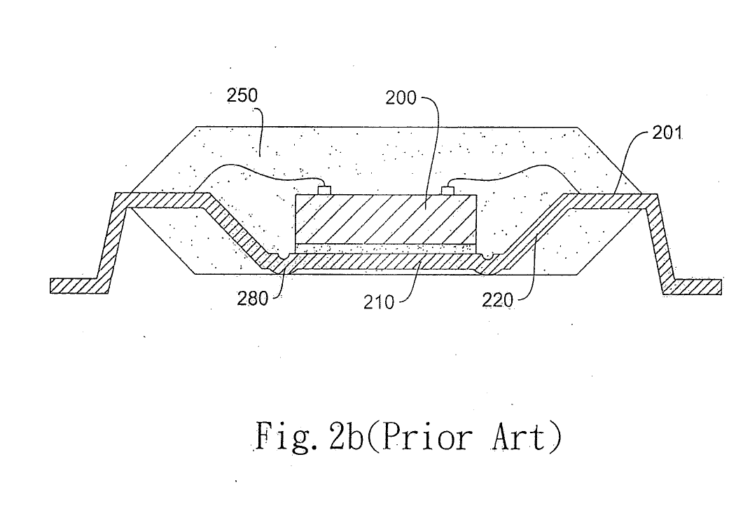

### DETAILED DESCRIPTION OF THEE INVENTION

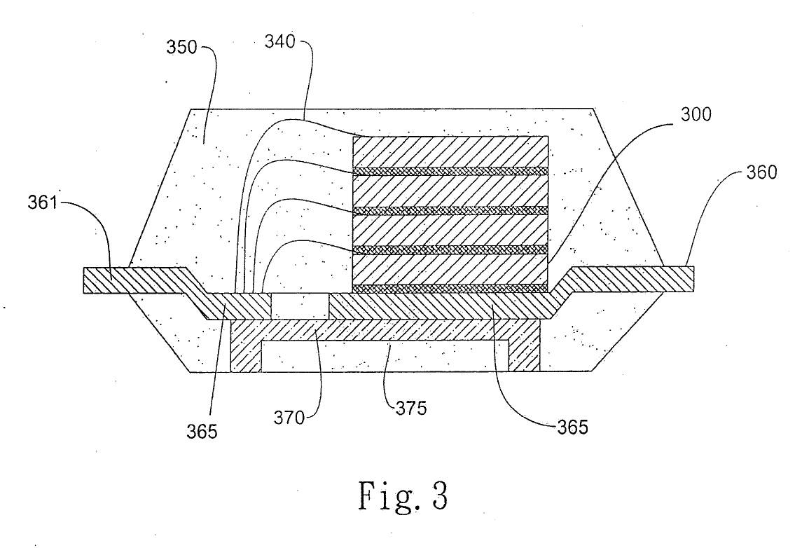

Refer to FIG. 3 a sectional view schematically showing a lead frame and chip package structure according to one embodiment of the present invention. In this embodiment, the lead frame and chip package structure of the present invention comprises a plurality of leads 360, a plurality of chips 300, a plurality of connecting wires 340, a support member 370, and a resin encapsulant 350. The leads, 360 include a plurality of inner leads 365 and a plurality of outer leads 361. The outer leads 361 jointly define a first plane. The inner leads 365 are connected to the outer leads 361 and are bent downward and then extended horizontally to jointly define a second plane. The chips 300 are arranged on the upper surface of a portion of the inner leads 365. The connecting wires 340 electrically connect the chips 300 to the other inner leads 365. The support member 370 is arranged on the lower surface of the inner leads 365. The support member 370 has a fillister 375; the fillister 375 has an opening, and the backside of the opening faces the inner leads 365. The resin encapsulant 350 encapsulates the leads 360, the chip 300, the connecting wires 340 and the support member 370 and fills up the fillister 375 but reveals a portion of the outer leads 361 and a portion of the support member 370.

In the abovementioned embodiment, the resin encapsulant 350 is molded by a mold (not shown in the drawings). The mold supports a portion of the lower surface of the support member 370. During resin injection, the mold not only provides a casing to cover the leads 360, the chips 300 and the connecting wires 340 but also props up a portion of the lower surface of the support member 370 carrying the inner leads 365. Thus, the support member 370 of the present invention can counterbalance the vertical pressure difference of the resin flow during resin injection of molding and can bear more chips stacked thereon. Thereby, the present invention effectively promotes the quality of the chip package structure.

In the abovementioned embodiment the upper surfaces of the chips 300 are active faces having a plurality of solder pads (not shown in the drawings), and the connecting wires 340, such as gold wires, electrically connect the solder pads to the inner leads 365. In the same embodiment, the support member 370 is made of a non-conductive material. In another embodiment, the connecting wires 340 electrically connect the chips 300 to all the inner leads 365 (not shown in the drawings).

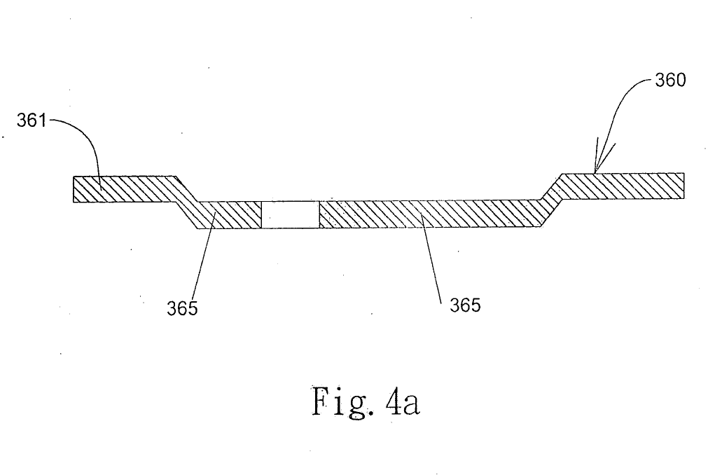

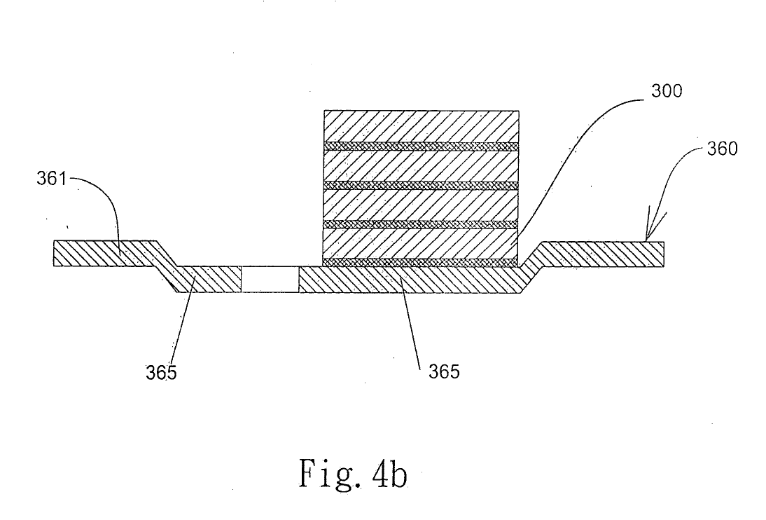

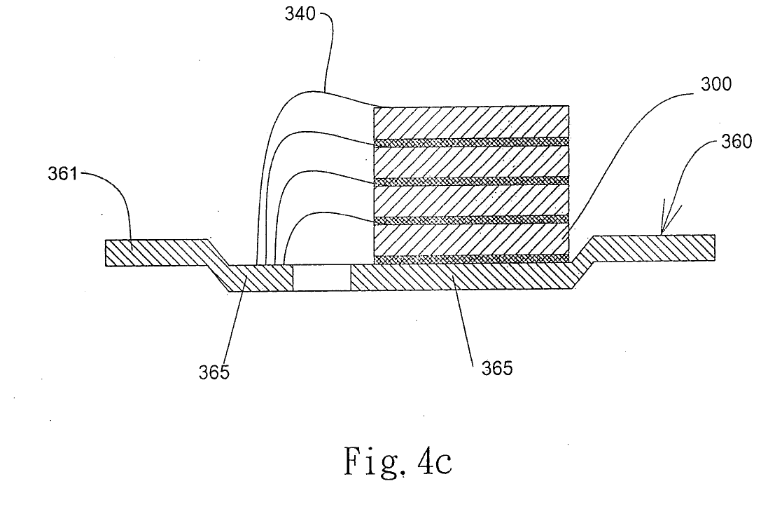

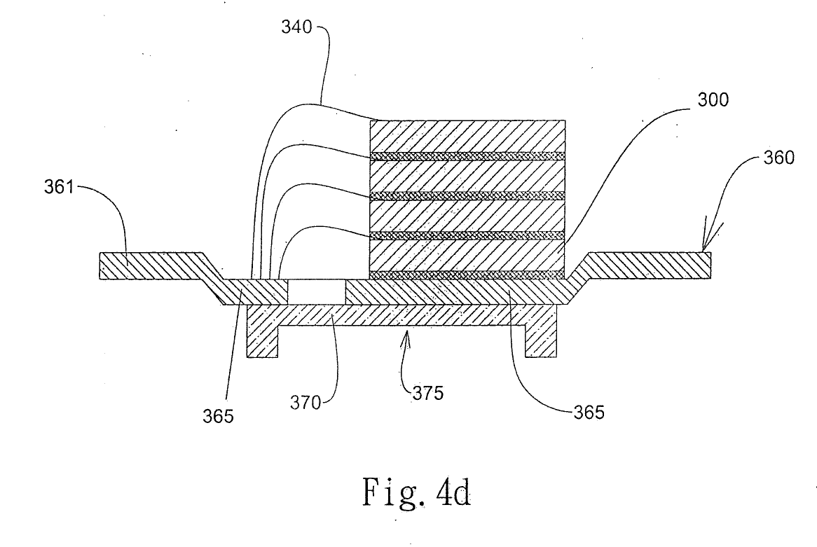

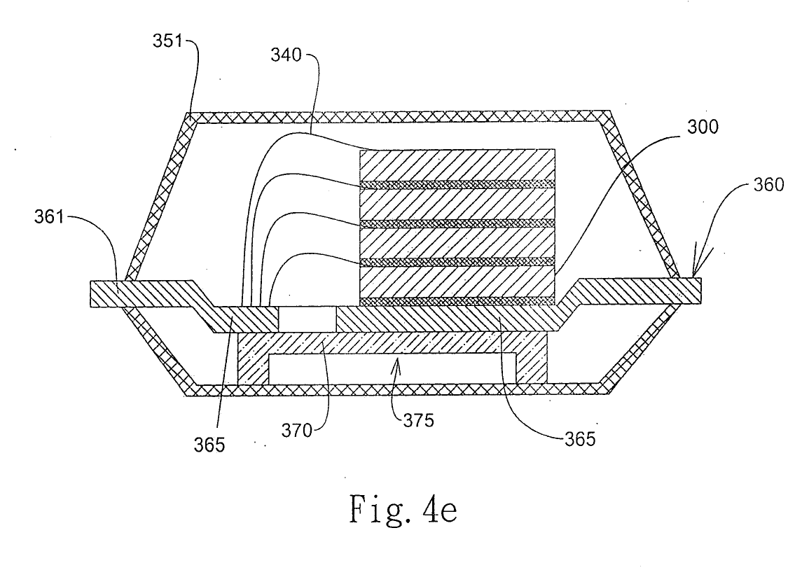

Refer to from FIG. 4a to FIG. 4e sectional views schematically the steps of a method of fabricating a lead frame and chip package structure according to one embodiment of the present invention. Firstly, as shown in FIG. 4a, a plurality of leads 360 is provided wherein the leads 360 include a plurality of inner leads 365 and a plurality of outer leads 361. The outer leads 361 jointly define a first plane. The inner leads 365 are connected to the outer leads 361 and are bent downward and then extended horizontally to jointly define a second plane. Next, as shown in FIG. 4b, a plurality of chips 300 is stacked on the upper surface of the inner leads 365. Next, as shown in FIG. 4c, a plurality of connecting wires 340 is used to electrically connect the chips 300 to the other inner leads 365. Next, as shown in FIG. 4d, a support member 370 is stuck to the backside of the inner leads 365. The support member 370 has a fillister 375; the fillister 375 has an opening, and the backside of the opening faces the inner leads 365. Next, as shown in FIG. 4e, a mold 351 having a mold cavity is used to encase the lead frame and the chips 300 and prop up the support member 370 with a portion of the outer leads 361 revealed. Then, a resin is injected into the mold cavity to encapsulate the leads 360, the chip 300, the connecting wires 340 and the support member 370 and fill up the fillister 375, but a portion of the outer leads 361 and a portion of the support member 370 are revealed. Thus is completed the lead frame and chip package structure shown in FIG. 3. The support member 370 supports the inner leads 365 by one side and contacts the mold 351 by the other side. Thereby, the support member 370 can provide a support force to counterbalance the vertical pressure difference of the resin flow during resin injection of molding. Therefore, the present invention can effectively improve the positioning of the structure inside the resin encapsulant and promote the quality of the chip package. In another embodiment, the support member 370 is stuck to the mold 351 and props up the inner leads 365 of the lead frame. Thus is also overcome the problem that the leads 360 are displaced during molding.

In the abovementioned embodiment, the upper surfaces of the chips 300 are active faces having a plurality of solder pads (not shown in the drawings), and the connecting wires 340, such as gold wires, electrically connect the solder pads to the inner leads 365. In another embodiment, the connecting wires 340 electrically connect the chips 300 to all the inner leads 365 (not shown in the drawings).

In conclusion, the present invention provides a lead frame and chip package structure and a method for fabricating the same, which features a support member arranged on the lower surface of the inner leads to support the inner leads. During resin injection of molding, the support member is propped against the mold, and the resin fills up the fillister of the support member, and the outer leads and the surface of the support member are partially revealed. Therefore, the support member can overcome the vertical pressure difference of the resin flow during resin injection. Further, the support member can also secure the components inside the resin encapsulant lest the structure be distorted. Thus, the quality of the chip package is promoted.

The embodiments described above are to demonstrate the technical contents and characteristics of the present invention to enable the persons skilled in the art to understand, make, and use the present invention. However, it is not intended to limit the scope of the present invention. Therefore, any equivalent modification or variation according to the spirit of the present invention is to be also included within the scope of the present invention.

What is claimed is:

1. A lead frame and chip package structure comprising
a plurality of leads including a plurality of inner leads and a plurality of outer leads, wherein said outer leads jointly define a first plane, and said inner leads are connected to said outer leads and bent downward and then extended horizontally to jointly define a second plane;
a plurality of chips arranged on a portion of said inner leads;
a plurality of connecting wires electrically connecting said chips to other said inner leads;
a support member arranged on a lower surface of said inner leads and having a fillister with an opening, wherein a backside of said opening faces said inner leads; and
a resin encapsulant covering said leads, said chips, said connecting wires and said support member, and filling up said fillister with a portion of said outer leads and a portion of surface of said support member being revealed.

2. The lead frame and chip package structure according to claim 1, wherein upper surfaces of said chips have a plurality of solder pads.

3. The lead frame and chip package structure according to claim 2, wherein said connecting wires electrically connect said solder pads to said inner leads.

4. The lead frame and chip package structure according to claim 1, wherein said connecting wires electrically connect said chips to all said inner leads.

5. The lead frame and chip package structure according to claim 1, wherein said support member is made of a non-conductive material.

6. A method for fabricating a lead frame and chip package structure comprising steps:
providing a plurality of leads including a plurality of inner leads and a plurality of outer leads, wherein said outer leads jointly define a first plane, and said inner leads are connected to said outer leads and bent downward and then extended horizontally to jointly define a second plane;
stacking a plurality of chips on an upper surface of a portion of said inner leads;
using a plurality of connecting wires to electrically connect said chips to other said inner leads;
arranging a support member on a lower surface of said inner leads, wherein said support member has a fillister with an opening, and a backside of said opening faces said inner leads;
providing a mold with a mold cavity, wherein said mold props up said support member and reveals a portion of said outer leads; and
injecting a resin encapsulant to cover said leads, said chips, said connecting wires and said support member and fill up said fillister with a portion of said outer leads aid a portion of surface of said support member being revealed.

7. The method for fabricating a lead frame and chip package structure according to claim 6, wherein a plurality of solder pads is formed on upper surfaces of said chips.

8. The method for fabricating a lead frame and chip package structure according to claim 7, wherein said connecting wires electrically connect said solder pads to a portion of said inner leads.

9. The method for fabricating a lead frame and chip package structure according to claim 6, wherein said connecting wires electrically connect said chips to all said inner leads.
